(19) United States
(12) Patent Application Publication
(10) Pub. No.: US 2006/0177775 A1
(43) Pub. Date: Aug. 10, 2006

(54) Method for manufacturing plate having electrode with gaps

(75) Inventors: Yun Szu Liu, Miao-Li (TW); Tsau Hua Hsieh, Miao-Li (TW); Sheng-Shiou Yeh, Miao-Li (TW)

Correspondence Address: WEI TE CHUNG;FOXCONN INTERNATIONAL, INC., 1650 MEMOREX DRIVE, SANTA CLARA, CA, 95050, US

(73) Assignee: INNOLUX DISPLAY CORP.

(21) Appl. No.: 11/348,734

(22) Filed: Feb. 6, 2006

(30) Foreign Application Priority Data
Feb. 4, 2005 (TW) 94103785

(51) Int. Cl. G03F 7/00

(52) U.S. Cl. 430/313; 430/319

(57) ABSTRACT

A method for manufacturing a plate (21) having an electrode (214) with a plurality of gaps (217) is provided. The method includes the steps of: providing a substrate (200) comprising a glass layer (210); coating a plurality of photo-resist protrusions (215) on the substrate; coating a transparent conductive layer (218) on the photo-resist protrusions and the substrate; removing the photo-resist protrusions and corresponding portions of the transparent conductive layer, thereby forming a plurality of gaps in the transparent conductive layer. The method of the preferred embodiment can provide a simplified process at a lower cost, compared with conventional methods requiring etching t.

### FIELD OF THE INVENTION

The present invention relates to methods for manufacturing liquid crystal display (LCD) components, and particularly to a method for manufacturing a plate including an electrode.

### BACKGROUND

Referring to FIG. 6, this shows a conventional liquid crystal display. The conventional liquid crystal display 1 includes a first plate 11, a second plate 12, and a liquid crystal layer 16 including a plurality of liquid crystal molecules 160 interposed between the first and second plates 11, 12. The first plate 11 includes a first glass layer 110, a black matrix layer 111 arranged on the first glass layer 110, a color filter layer 112 deposited on the first glass layer 110 and the black matrix layer 111, a protective layer 113 formed on the color filter layer 112, and a common electrode 114 formed on the protective layer 113. The second plate 12 includes a second glass layer 120, and a plurality of pixel electrodes 121 arranged on the second glass layer 120.

The common electrode 114 is a plane electrode, and includes a plurality of gaps 117. The common electrode 114 is a transparent conductive layer, which is made of indium tin oxide (ITO) or indium zinc oxide (IZO). When a voltage is applied, the pixel electrodes 121 and the common electrode 114 generate an electric field to control orientations of the liquid crystal molecules 160. The gaps 117 divide the common electrode 114 into a plurality of separate portions, to improve the characteristics of the electric field.

Referring to FIG. 7, this shows a method for manufacturing the first plate 11. The method includes the steps of: providing a glass layer; coating a black matrix on the glass layer; coating a color filter layer on the glass layer and the black matrix; coating a protective layer on the color filter layer; and forming a common electrode on the protective layer.

Details of a process for forming the common electrode 114 are shown in FIG. 8 through FIG. 13. Referring to FIG. 8, the process for forming the common electrode 114 includes the steps of: coating a transparent conductive layer on the protective layer; coating a photo-resist layer on the protective layer; developing the photo-resist layer; etching the transparent conductive layer; and removing residual photo-resist.

Referring to FIG. 9, the black matrix layer 111, the color filter layer 112 and the protective layer 113 are formed in that order on the first glass layer 110. A transparent conductive layer 118 is then arranged on the protective layer 113. The protective layer 113 is made of propylene resin or epoxy resin. The transparent conductive layer 118 is made of indium tin oxide (ITO) or indium zinc oxide (IZO).

Referring to FIG. 10, a photo-resist layer 115 is coated on the transparent conductive layer 118. The photo-resist layer 115 is made of positive photo-resist material.

Referring to FIG. 11, an ultraviolet light source is used to illuminate a plurality of predetermined portions of the photo-resist layer 115. Then an acidic solution is used to dissolve the illuminated portions of the photo-resist layer 115 and thereby develop a plurality of openings 116. In another words, this step uses a photolithography process (that is, a photo mask process) to form the openings 116.

Referring to FIG. 12, the transparent conductive layer 118 is etched at positions corresponding to the openings 116. This is performed by way of a dry-etching process or a wet-etching process. Thus, the gaps 117 are formed in the transparent conductive layer 118.

Referring to FIGS. 12 and 13, residual portions of the photo-resist layer 115 are removed, thereby providing the common electrode 114 with the gaps 117. Accordingly, the finished first plate 11 is obtained.

As described above, a photo mask process and an etching process must be used to obtain the first plate 11. The photo mask process and the etching step involve relatively complex steps and high cost. Correspondingly, the method for manufacturing the first plate 11 is unduly complex and costly.

What is needed, therefore, is a relatively simple and inexpensive method for manufacturing a plate with a common electrode.

### SUMMARY

In a preferred embodiment, a method for manufacturing a plate including an electrode with a plurality of gaps is provided. The method includes the steps of: providing a substrate comprising a glass layer; coating a plurality of photo-resist protrusions on the substrate; coating a transparent conductive layer on the photo-resist protrusions and the substrate; removing the photo-resist protrusions and corresponding portions of the transparent conductive layer, thereby forming a plurality of gaps in the transparent conductive layer.

As description in the above, the method of the preferred embodiment can obtain the plate including the electrode with the gaps without the need for an etching process. Therefore, the method of the preferred embodiment can provide a simplified process at a lower cost, compared with conventional methods requiring etching.

Other advantages and novel features will become more apparent from the following detailed description when taken in conjunction with the accompanying drawings, in which:

### BRIEF DESCRIPTION OF THE DRAWINGS

FIG. 1 is a schematic, cross-sectional view of part of an LCD comprising a first plate, the first plate being made according to a preferred embodiment of the present invention;

FIG. 2 is a flow chart of a process for forming a common electrode of the first plate shown in FIG. 1, according to a preferred embodiment of the present invention;

FIG. 3 is a schematic, cross-sectional view of part of a first substrate provided in accordance with the process shown in FIG. 2, showing a photo-resist protrusion formed on a protective layer of the first substrate;

FIG. 4 is similar to FIG. 3, but showing a transparent conductive layer formed on the photo-resist protrusion and the protective layer in accordance with the process shown in FIG. 2;

FIG. 5 is similar to FIG. 4, but showing a gap formed in the transparent conductive layer in accordance with the process shown in FIG. 2, the transparent conductive layer thus constituting a common electrode;

FIG. 6 is a schematic, cross-sectional view of part of a conventional LCD, the LCD comprising a first plate;

FIG. 7 is a flow chart of a conventional method for manufacturing the first plate shown in FIG. 6, the method including forming a common electrode;

FIG. 8 is a flow chart of a conventional process for forming the common electrode according to the method shown in FIG. 7;

FIG. 9 is a schematic, cross-sectional view of part of a substrate provided in accordance with the process shown in FIG. 8, showing a transparent conductive layer coated on a protective layer of the substrate;

FIG. 10 is similar to FIG. 9, but showing a photo-resist layer formed on the transparent conductive layer in accordance with the process shown in FIG. 8;

FIG. 11 is similar to FIG. 10, but showing an opening formed in a predetermined portion of the photo-resist layer in accordance with the process shown in FIG. 8;

FIG. 12 is similar to FIG. 11, but showing a gap formed in the transparent conductive layer corresponding to the opening, in accordance with the process shown in FIG. 8; and

FIG. 13 is similar to FIG. 12, but showing the structure after residual photo-resist has been removed in accordance with the process shown in FIG. 8.

### DETAILED DESCRIPTION OF PREFERRED EMBODIMENTS

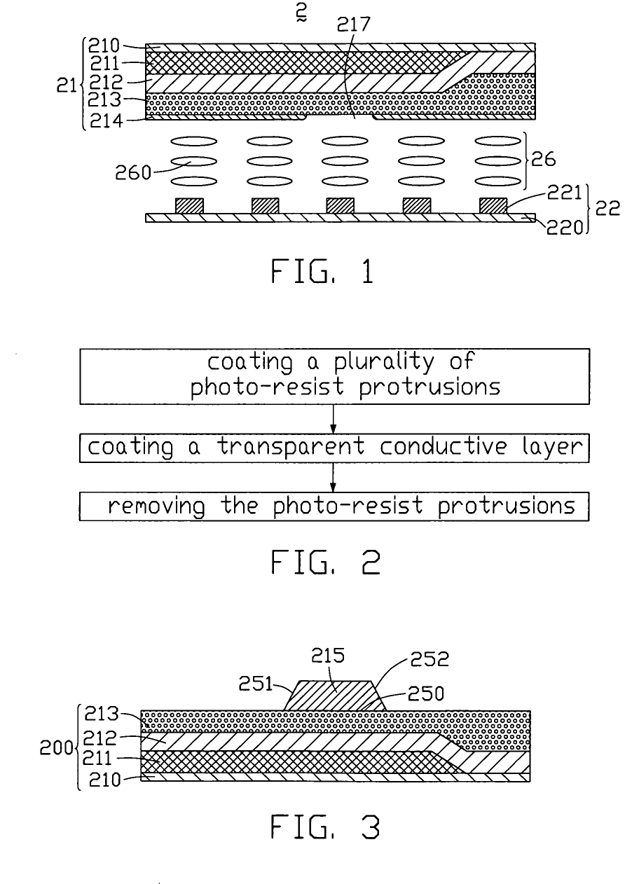

Referring to FIG. 1, this shows part of a liquid crystal display 2. The liquid crystal display 2 includes a first plate 21, a second plate 22, and a liquid crystal layer 26 interposed between the first and second plates 21, 22. The first plate 21 includes a first glass layer 210, a black matrix layer 211 arranged on the first glass layer 210, a color filter layer 212 deposited on the first glass layer 210 and the black matrix layer 211, a protective layer 213 formed on the color filter layer 212, and a common electrode 214 formed on the protective layer 213. The second plate 22 includes a second glass layer 220, and a plurality of pixel electrodes 221 arranged on the second glass layer 220. The common electrode 214 is a plane electrode, and includes a plurality of gaps 217. Further, the common electrode 214 is a transparent conductive layer, which is made of indium tin oxide (ITO) or indium zinc oxide (IZO).

In a preferred embodiment, a method for manufacturing the first plate 21 includes the steps of: providing a glass layer; coating a black matrix on the glass layer; coating a color filter layer on the glass layer and the black matrix; coating a protective layer on the color filter layer; and forming a common electrode on the protective layer.

Details of a process for forming the common electrode 214 are shown in FIG. 2 through FIG. 5. Referring to FIG. 2, the process for forming the common electrode 214 includes the steps of: coating a plurality of photo-resist protrusions on the protective layer; coating a transparent conductive layer on the photo-resist protrusions and the protective layer; and removing the photo-resist protrusions.

Referring to FIG. 3, the black matrix layer 211, the color filter layer 212 and the protective layer 213 are provided on the glass layer 210 in that order, thereby forming a first substrate 200. Then pluralities of photo-resist protrusions 215 are formed on the protective layer 213. The protective layer 213 is made of propylene resin or epoxy resin. The photo-resist protrusions 215 are made of positive photo-resist material. Each of the photo-resist protrusions 215 has a trapezoidal cross-section. In particular, the photo-resist protrusion 215 has a bottom side 250 arranged on the protective layer 213, and two oblique sides 251, 252 respectively adjoining the bottom side 250. The oblique sides 251, 252 are not parallel with each other. The trapezoidal cross-section defines two base angles where the bottom side 250 adjoins the oblique sides 251, 252, respectively. Each of the base angles is an acute angle close to 90°. Such as, each of the base angles is 85° or more, and preferably 87° or more. That is, the oblique sides 251, 252 are almost perpendicular to the bottom side 250.

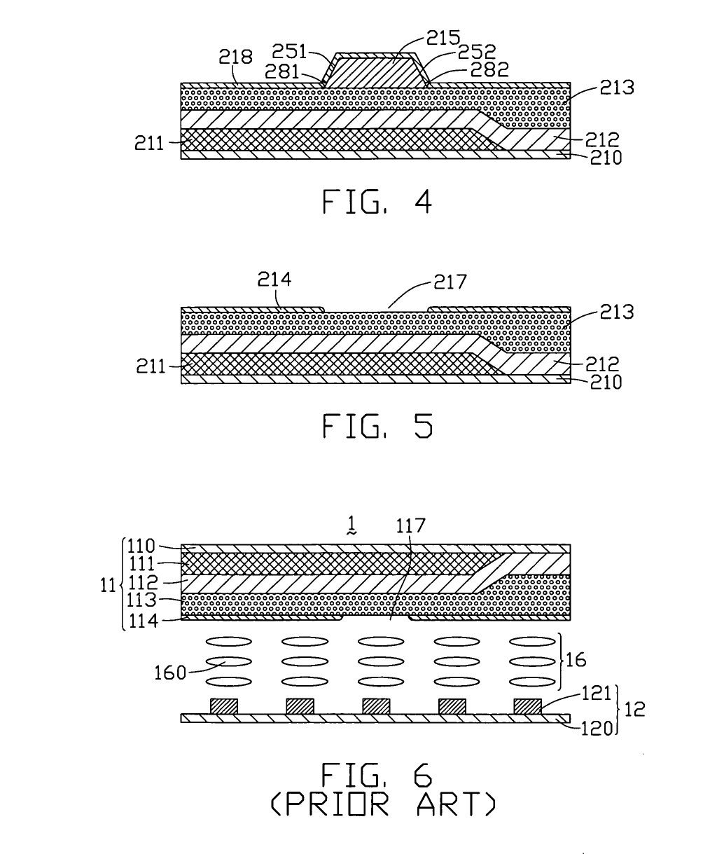

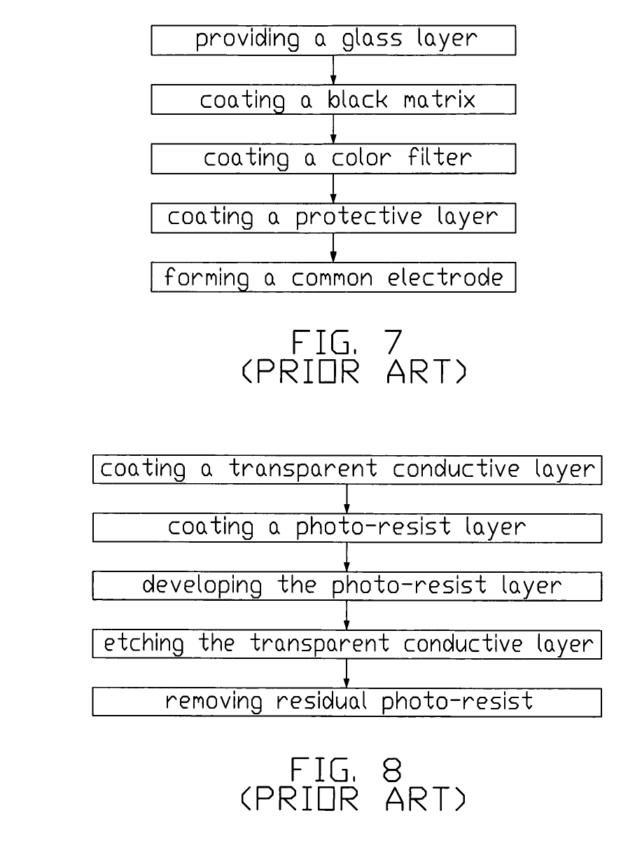

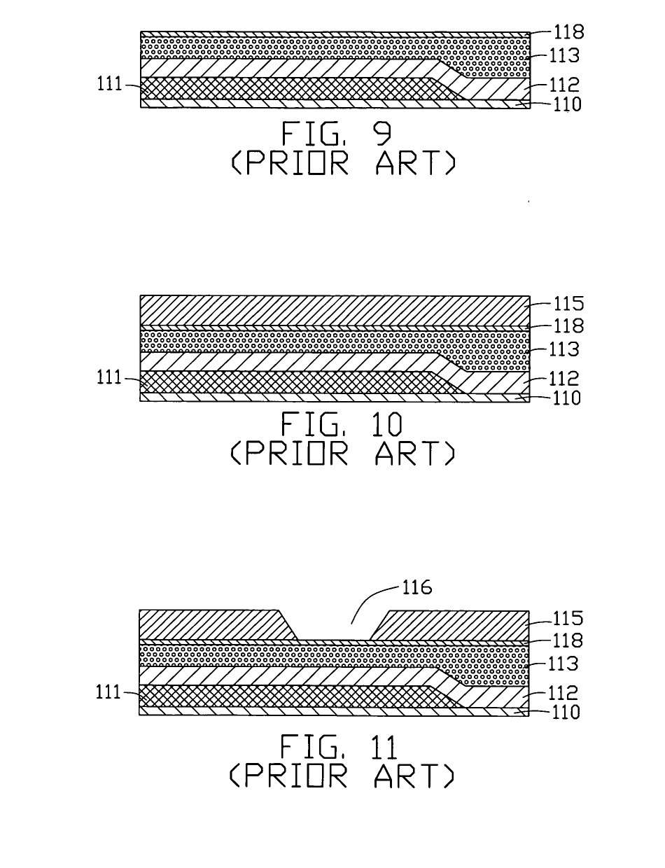

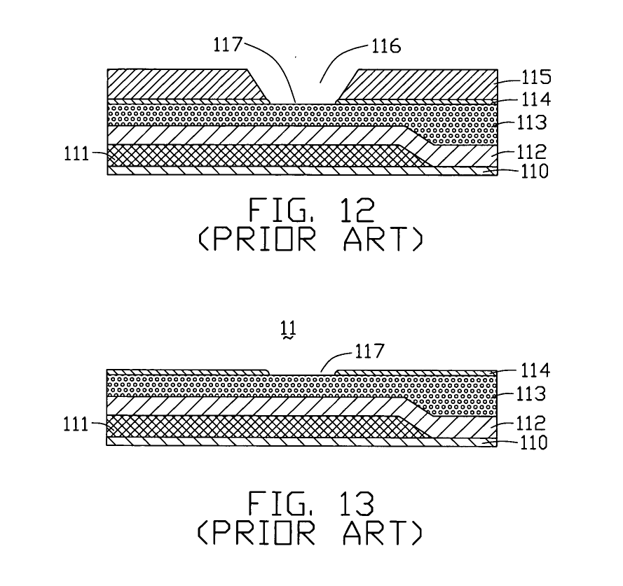

Referring to FIG. 4, a transparent conductive layer 218 is formed on the photo-resist protrusions 215 and the protective layer 213. A thickness of the transparent conductive layer 218 is generally less than 1 μm. Because the oblique sides 251, 252 of each photo-resist protrusion 215 are almost perpendicular to the protective layer 213, when the transparent conductive layer 218 is formed, a pair of slits 281, 282 may be created in the transparent conductive layer 218. The slits 281, 282 are respectively located where the oblique sides 251, 252 adjoin the protective layer 213.

Referring to FIG. 5, the photo-resist protrusions 215 are removed, thereby forming the common electrode 214 with the gaps 217. Detailedly, an ultraviolet light source is used to illuminate the transparent conductive layer 218 and the underlying photo-resist protrusions 215. Because the photo-resist protrusions 215 are positive photo-resist, an acidic solution is used to dissolve the illuminated photo-resist protrusions 215 and the illuminated transparent conductive layer 218. Thereby, the gaps 217 are developed. Thus, the first plate 21 including the common electrode 214 with the gaps 217 is obtained.

The above-described method of the preferred embodiment can provide the first plate 21 including the common electrode 214 with the gaps 217 without the need for an etching process. Therefore the method of the preferred embodiment can provide a simplified process at a lower cost, compared with conventional methods requiring etching.

In an alternative preferred embodiment, the photo-resist protrusions 215 may be made of negative photo-resist material. Negative photo-resist can be dissolved by an acidic solution without being first illuminated by ultraviolet light. Therefore the transparent conductive layer 218 and the underlying photo-resist protrusions 215 can be removed without the need for an ultraviolet light source and corresponding illumination. In such case, the method according to the alternative preferred embodiment can provide an even more simplified process at an even lower cost.

It is to be further understood that even though numerous characteristics and advantages of various embodiments have been set forth in the foregoing description, together with details of the structures and functions of the embodiments, the disclosure is illustrative only, and changes may be made in detail to the full extent indicated by the broad general meaning of the terms in which the appended claims are expressed.

What is claimed is:

1. A method for manufacturing a plate having an electrode with a plurality of gaps, comprising the steps of:
providing a substrate comprising a glass layer;
coating a plurality of photo-resist protrusions on the substrate;
coating a transparent conductive layer on the photo-resist protrusions and the substrate;
removing the photo-resist protrusions and corresponding portions of the transparent conductive layer, thereby forming a plurality of gaps in the transparent conductive layer.

2. The method as recited in claim 1, wherein the photo-resist protrusions are made of positive photo-resist material.

3. The method as recited in claim 2, wherein the step of removing the photo-resist protrusions and corresponding portions of the transparent conductive layer comprises using ultraviolet light to illuminate the portions of the transparent conductive layer and the photo-resist protrusions.

4. The method as recited in claim 1, wherein the photo-resist protrusions are made of negative photo-resist material.

5. The method as recited in claim 4, wherein the step of removing the photo-resist protrusions and corresponding portions of the transparent conductive layer comprises using an acidic solution to dissolve the portions of the transparent conductive layer and the photo-resist protrusions.

6. The method as recited in claim 1, wherein the electrode is made of indium tin oxide and/or indium zinc oxide.

7. The method as recited in claim 1, wherein the substrate further comprises a black matrix, a color filter, and a protective layer arranged in that order on the glass layer.

8. The method as recited in claim 7, wherein in the step of coating a plurality of photo-resist protrusions on the substrate, the photo-resist protrusions are coated on the protective layer.

9. The method as recited in claim 1, wherein each of the photo-resist protrusions has a trapezoidal cross-section, the photo-resist protrusion having a bottom side adjacent the substrate and two oblique sides adjacent the bottom side.

10. The method as recited in claim 9, wherein the oblique sides are approach perpendicularity relative to the bottom side.

11. The method as recited in claim 9, wherein the trapezoidal cross-section defines two base angles corresponding to where the bottom side adjoins the oblique sides, and the base angles are close to 90°.

12. The method as recited in claim 9, wherein the electrode is a common electrode for a liquid crystal display.
